(19) United States
(12) Patent Application Publication
(10) Pub. No.: US 2012/0189408 A1
(43) Pub. Date: Jul. 26, 2012

(54) METHOD AND APPARATUS FOR WAFER SUPPORT

(75) Inventor: Anthony C. Bonora, Fremont, CA (US)

(73) Assignee: CROSSING AUTOMATION, INC., Fremont, CA (US)

(21) Appl. No.: 13/436,304

(22) Filed: Mar. 30, 2012

Related U.S. Application Data
(63) Continuation of application No. 12/253,212, filed on Oct. 16, 2008.
Application No. 12/253,212 is a continuation of application No. 11/433,366, filed on May 12, 2006, now abandoned.
(60) Provisional application No. 60/980,763, filed on Oct. 17, 2007.
(60) Provisional application No. 60/983,110, filed on Oct. 26, 2007.
(60) Provisional application No. 60/697,528, filed on Jul. 8, 2005.

(51) Int. Cl. H01L 21/677; B65D 25/10

(52) U.S. Cl. 414/222.01; 220/694

(57) ABSTRACT

An end effector having a first arm and a second arm extending from an end effector support body is provided. The first arm and the second arm each have support extensions for supporting a peripheral region of a substrate on opposing sides of a diameter of the substrate. The height of support contacts on opposing sides of the diameter is different relative to a horizontal datum plane. In one embodiment, the end effector includes additional arms extending from the end effector support body. A system for supporting a substrate is provided also.

### CLAIM OF PRIORITY

The present application is a continuation of and claims the benefit of and priority under 35 U.S.C. §120 from U.S. patent application Ser. No. 12/253,212, filed on Oct. 16, 2008, which is hereby incorporated by reference in its entirety for all purposes.

The U.S. patent application Ser. No. 12/253,212 claims the benefit of and priority under 35 U.S.C. §119(e) from U.S. Provisional Patent Application Nos. 60/980,763, filed Oct. 17, 2007, and 60/983,110, filed on Oct. 26, 2007, and is a continuation-in-part of U.S. application Ser. No. 11/483,366, filed on Jul. 7, 2006, which claims the benefit of and priority under 35 U.S.C. §119(e) from U.S. Provisional Application 60/697,528, filed on Jul. 8, 2005, all of which are hereby incorporated by reference in their entirety for all purposes.

### BACKGROUND

The manufacturing of semiconductor components relies on automation for yield and cleanliness purposes. The transfer of substrates to and from front opening unified pods (FOUPs) and process tools is one area where losses can take place in the form of damage to the substrates or damage to the end effectors moving the substrates. In addition, as substrates transition from 300 millimeter to 450 millimeter diameters, the support of the substrates within a container and during transport on an end effector may be impacted. Current systems are unable to account for or alleviate the deflection experienced by a wafer when being stored or transported. This deflection may result in damage to the semiconductor devices on the substrate.

Accordingly, improvements are needed in order to adjust for wafer deflection when storing and transporting the semiconductor substrates.

### SUMMARY

Broadly speaking, the present invention fills these needs by providing an architecture for a transport system within a fabrication facility. It should be appreciated that the present invention can be implemented in numerous ways, including as a method, a system, or an apparatus. Several inventive embodiments of the present invention are described below.

In one embodiment, an end effector having an end effector support body. A first arm extends from the end effector support body and a second arm extends from the end effector support body. The first arm and the second arm each have support extensions for supporting a peripheral region of a substrate on opposing sides of a diameter of the substrate. The height of support contacts on opposing sides of the diameter is different relative to a horizontal datum plane. In one embodiment, the end effector includes additional arms extending from the end effector support body.

In another embodiment, a system for transporting a substrate. The system includes a substrate container having a support structure disposed within a housing assembly. The support structure has a plurality of support extensions extending into an inner region of the housing assembly. The plurality of support extensions are arranged as horizontally coplanar pairs, wherein support extensions of different horizontal planes are vertically aligned. The system includes an end effector adapted to support a peripheral region of the substrate outside of the horizontally coplanar pairs of a surface of a substrate housed within the substrate container. The end effector has a first arm extending from an end effector support body, and a second arm extending from the end effector support body. The first and the second arms support the substrate at support points proximate to support points of the support extensions of the substrate container.

Other aspects and advantages of the invention will become apparent from the following detailed description, taken in conjunction with the accompanying drawings, illustrating by way of example the principles of the invention.

### BRIEF DESCRIPTION OF THE DRAWINGS

Aspects of the present invention will become apparent from the following detailed description, taken in conjunction with the accompanying drawings, illustrating by way of example the principles of the invention.

FIGS. 1A through 1C are simplified schematic diagrams illustrating a top view of a container and end effector in accordance with one embodiment of the invention.

FIGS. 2A and 2B illustrate side and front elevation views, respectively, of container 102 in accordance with one embodiment of the invention.

FIG. 3 is another exemplary embodiment illustrating an alternative container support arm structure and end effector support structure in accordance with one embodiment of the invention.

FIGS. 4A-I illustrate a plurality of patterns which may be used within a container for supporting a semiconductor substrate in accordance with one embodiment of the invention.

FIGS. 5A and 5B illustrate alternative embodiments for the support structures of the container and end effectors in accordance with one embodiment of the invention.

FIG. 6 is a simplified schematic diagram of a container in accordance with one embodiment of the invention.

FIGS. 7A through 7C are simplified schematic diagrams illustrating a top view of a container and end effector for supporting a substrate in accordance with one embodiment of the invention.

FIGS. 8A through 8E illustrate a container configured to support substrates in accordance with one embodiment of the invention.

FIGS. 9A and 9B illustrate a smaller capacity front opening unified pod (FOUP) in accordance with one embodiment of the invention.

FIGS. 10A through 10C illustrate an alternative end effector design in accordance with one embodiment of the invention.

FIGS. 11A and 11B illustrate a side and front view, respectively, of container 102 in accordance with one embodiment of the invention.

FIG. 12 is a simplified schematic diagram illustrating areas of support for substrate or semiconductor wafer 122.

FIGS. 13A through 16B illustrate various modeling diagrams depicting support deflection due to gravity and its impact on the wafer.

### DETAILED DESCRIPTION

An invention is described for an end effector and a system for handling semiconductor substrates involved in semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein include a semiconductor substrate container for storing semiconductor substrates within a structure that enables storage and transport of one or more of the substrates, as well as random access pick and place handling of individual substrates or groups of substrates. In one embodiment, a cantilevered structure that includes support points located within an inner diameter of a bottom surface of the supported substrate is provided. The support structure of the container is configured so as to leave an outer or peripheral edge (or a bottom surface of a peripheral region) of the semiconductor substrate exposed so that the peripheral edge or bottom surface of a peripheral region is accessible by an end effector for movement of the substrate. In one embodiment, the support structure supports the substrate from an inner diameter so that an end effector may grasp the substrate from the container by supporting the peripheral edge or a bottom surface of the substrate outside the inner diameter.

In addition, the embodiments described herein provide tailored support for a semiconductor substrate in order to provide the best average fit with regard to minimization of deflection or other stresses experienced by the substrate during storage or movement operations. It should be appreciated that the transition to a larger diameter wafer, i.e., the transition from 300 mm wafers to 450 mm wafers, may not be accompanied by a corresponding increase in thickness of the wafer, therefore, the embodiments described herein support the substrate in a manner that accounts for the increased stresses placed on the substrate. Consequently, the embodiments prevent possible damage to the semiconductor circuitry disposed on the surface of the substrate due to any increased stresses.

As will be explained in more detail below, in one embodiment, the support points contacting the surface of the substrate being supported are not coplanar relative to a horizontal datum plane. It should be noted that while the embodiments described illustrate designs of a container and end effector together, this is not meant to be limiting. That is, the embodiments of the container described herein may be used with or without the illustrated end effectors. For example, the containers described below may be utilized with any suitable conventional end effector, as well as the end effectors described below.

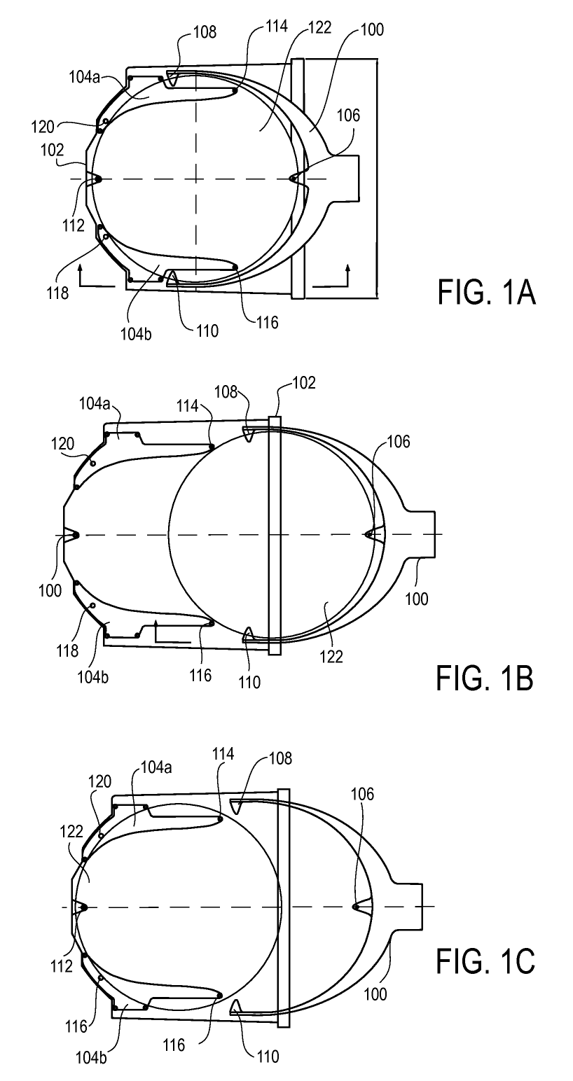

FIGS. 1A through 1C are simplified schematic diagrams illustrating a top view of a container and end effector in accordance with one embodiment of the invention. In FIG. 1A, semiconductor substrate 122 is supported by end effector 100 at points 106, 108 and 110. Within container 102, support contacts 112, 114, and 116 provide support for semiconductor substrate 122. One skilled in the art will appreciate that any number of support contacts may be provided on end effector 100 or container 102, and that the illustrations provided herein are exemplary and not meant to be limiting. That is, while FIGS. 1A-C illustrate three support contacts for the end effector and the container, the end effector and the container may include more than three support contacts. In addition, the number of support contacts on the container may be different than the number of support contacts on the end effector. End effector 100 includes support contact 106 at an outer edge of a bottom surface of substrate 122 closest to the support arm for the blades of the end effector, in addition to the opposing support points 108 and 110 at the outer edge of the bottom surface of the substrate. It should be noted that the opposing support points 108 and 110 extend past a diameter of substrate 122 into a circumferential portion of the substrate that does not contain the support contact 106 in accordance with one embodiment of the invention.

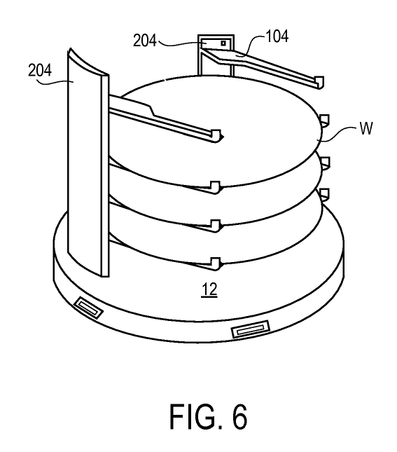

Container 102 may include back support point 112 in addition to a plurality of other support points, e.g., support points 114 and 116. Stops 120 and 118 are used to prevent wafer 122 from sliding towards a wall of container 102 in one embodiment. The stops may also be used to fix the position of the substrate. In another embodiment, a door to container 102 may provide pressure to keep substrates 122 firmly held between the door and stops 120 and 118 in one embodiment. FIGS. 1B and 1C illustrate views with end effector 100 at different points. In FIG. 1B, end effector 100 is supporting substrate 122 and in FIG. 1C end effector 100 is disengaged from the substrate, which is supported on the arms of container 102. In one embodiment, container 102 may include a plurality of cantilevered arms 104a and 104b disposed over each other in order to support a plurality of substrates 122, as illustrated in FIG. 6.

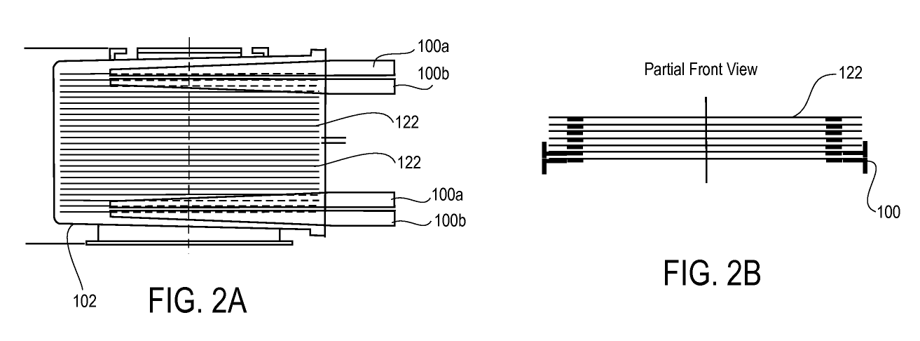

FIGS. 2A and 2B illustrate side and front elevation views, respectively, of container 102 in accordance with one embodiment of the invention. In FIG. 2A, a plurality of substrates is supported within container 102, wherein the plurality of substrates are spaced apart at a 10 mm wafer pitch. It should be appreciated that this wafer pitch is exemplary and not meant to be limiting. In one embodiment, multiple substrates 122 may be supported simultaneously by an end effector 100a and 100b. In this embodiment, a dual swap end effector 100a and 100b, enhances the efficiency of wafer pick and place operations. In FIG. 2A, the end effector arms for end effectors 100a and 100b are illustrated at a top position and a bottom position in order to provide a graphical illustration for the clearance of the arms to the bottom of container 102. It should be appreciated that the plan view of FIGS. 1A-C can include the dual swap end effector of FIGS. 2A and B. Each of substrates 122 is supported by arms extending from a back of container 102 in one embodiment. It should be appreciated that the supports for substrates 122 may be extended from a support rod or structure which is affixed to a top or bottom surface of container 102, as opposed to a side surface in another embodiment. It should be appreciated that the support arms illustrated in FIGS. 1A through 1C are exemplary in that numerous other configurations for support arms may be provided. Any support arm extending under an internal diameter of substrate 122 that enables an end effector to access an outer edge of the substrate would be suitable for the containers described herein.

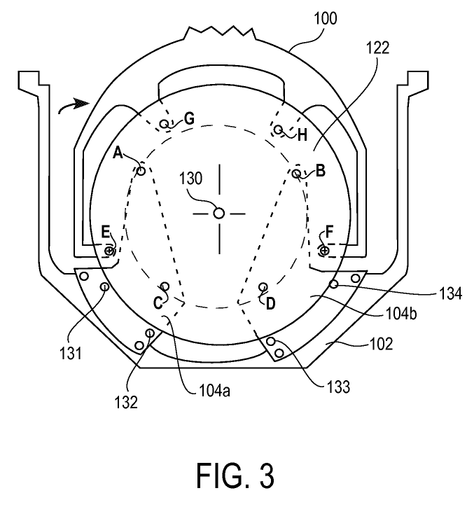

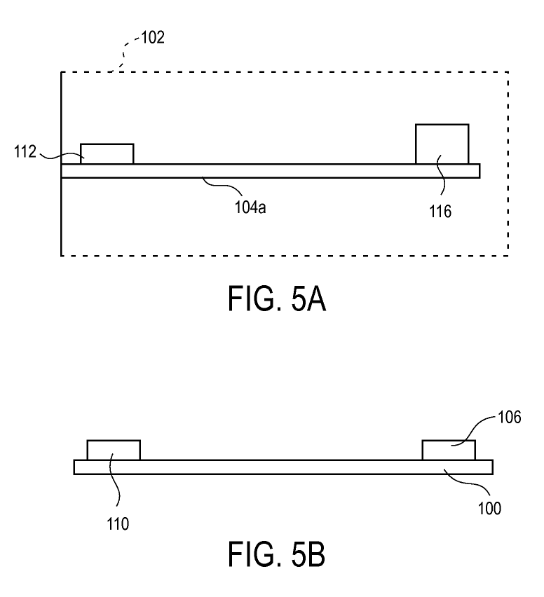

FIG. 3 is another exemplary embodiment illustrating an alternative container support arm structure and end effector support structure in accordance with one embodiment of the invention. End effector 100 includes four support contacts E, F, G and H, which are affixed to corresponding extensions emanating from an outer ring of the end effector. Container 102 includes four support points, A, B, C and D. Two of each of the support points A, B, C and D, are affixed to corresponding support arms 104a and 104b. As illustrated, container support arms 104a and 104b extend from a side surface of container 102 and enable access to an inner diameter of the back surface of substrate 122. In particular, support points E and F are located on an opposing side of a diameter of substrate 122, relative to the support arm for the outer ring of the end effector. In one embodiment, support arms 104a and 104b may be a single integral structure affixed to the container or alternatively, to an intermediate support structure. One skilled in the art will appreciate that conventional end effectors may be employed with the containers described herein, in addition to the external access end effectors described with reference to FIGS. 1A through 1C, and FIG. 3. In another embodiment, a planar height of a top surface of the support features disposed on the support contacts for the end effectors and/or the container may be offset from each other, as discussed with reference to FIG. 5. The support features may be pads or other suitable support surfaces compatible with the substrate.

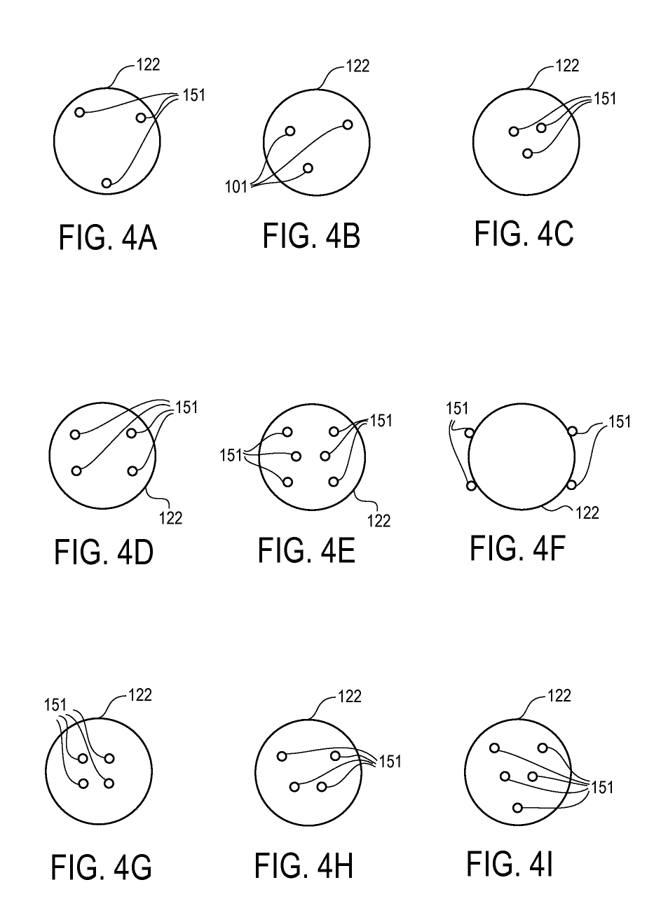

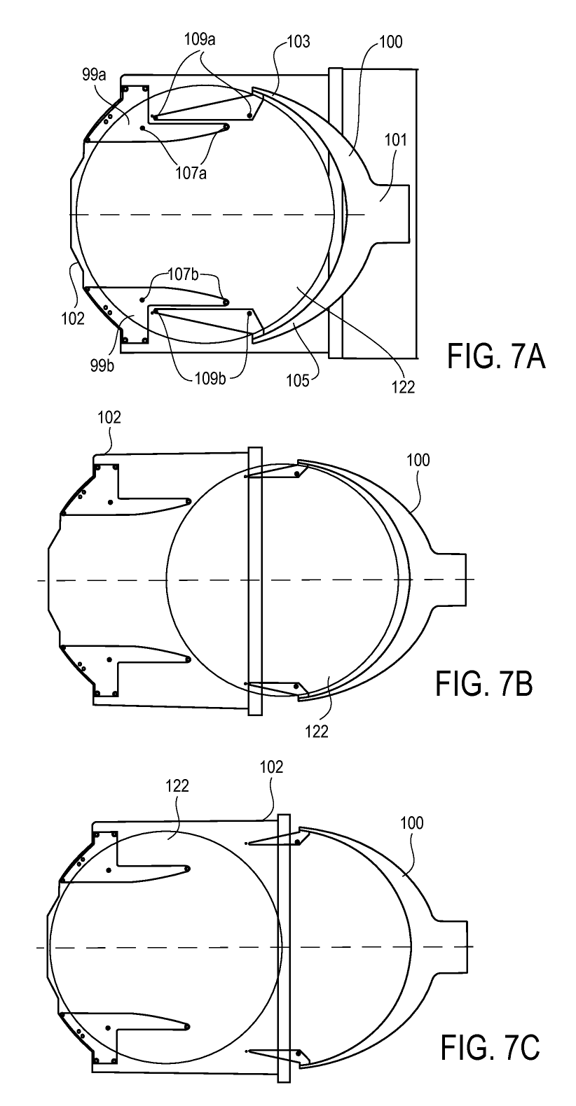

Still referring to FIG. 3, it should be noted that support points for container 102, as well as end effector 100, provide support to the backside of substrate 122 on opposing sides of the center of gravity point 130. That is, for container 102, support points A and B are located on one side of a diameter of substrate 122, while support points C and D are located on an opposing side of the diameter. Similarly with end effector 100, support points E and F are located on opposing sides of the diameter than support points G and H. In this embodiment, points G and H are inboard of the outer portions of support arms 104a and 104b, while points E and F are outboard of the outer portions of support arms 104a and 104b. In FIG. 3, the arm extensions of end effector 100 exceed the diameter of substrate 122. However, in alternative embodiments, the arm extensions may be less than the diameter of substrate 122, as depicted with reference to FIGS. 7A-C. Wafer position stops 131-134 are provided to prevent substrate 122 from hitting the back wall of container 102, and to possibly orient the substrate. Wafer position stops 131-134 may be protrusions extending from a top surface of support arms 104a and 104b so that an edge of substrate 122 contacts the stops. One skilled in the art will appreciate that numerous configurations for support arms 104a and 104b, as well as the support features disposed thereon may be provided. Exemplary patterns are provided with reference to FIG. 4. Similarly, the arm extensions and support extensions for end effector 100 may be manipulated to provide various support features at different locations. In one embodiment, end effector 100 includes support features contacting a peripheral region of the surface of substrate 122. The peripheral region may extend 80 millimeters from the outer edge of the substrate in one embodiment. However, this is not meant to be limiting as the peripheral region may extend further from the edge of the substrate. In addition, end effector 100 may include arm extensions extending into an internal or center region of the substrate in other embodiments.

FIGS. 4A-I illustrate a plurality of patterns which may be used within a container for supporting a semiconductor substrate in accordance with one embodiment of the invention. In each of FIGS. 4A-I substrate 122 is supported by a pattern of support points 151. It should be appreciated that these patterns are exemplary so that one skilled in the art will appreciate the numerous patterns available. Each of the support points support a bottom surface of substrate 122, except the embodiment of FIG. 4F, where the external edges of the substrate are supported. The patterns described and the support points illustrated will be utilized with container support arms as described with regards to the previous figures. It should be noted that the shape of the support arms will depend on the pattern selected and support structure. It should be noted that the support points of FIGS. 4A-I may also depict support point patterns for an end effector supporting substrate 122. The embodiments further depict the peripheral edge regions of the substrate being supported in some embodiments. The peripheral edge regions may be defined within an 80 millimeter boundary of the edge of the substrate in some embodiments, however, this is not meant to be limiting.

FIGS. 5A and 5B illustrate alternative embodiments for the support structures of the container and end effectors in accordance with one embodiment of the invention. In FIGS. 5A and 5B, the support structures are not planar relative to a horizontal datum plane. Alternatively, the structures on top of which the support features are disposed may be at different elevations In either instance, the pads or contacts on which a substrate will rest are not planar with respect to a horizontal datum plane. In FIG. 5A, container 102 illustrates a support arm 104A having support contacts 112 and 116 extending therefrom. Support contact 116 is taller than support contact 112. Thus, a top surface of support contact 116 is not planar with a top surface of support contact 112 relative to a horizontal datum plane. With this embodiment, the positioning of the support contacts and their elevation affect the peak deflection experienced by the wafer due to the large diameter relative to the thin substrate thickness. In one embodiment the deflection and stress is minimized, i.e., the stress is relieved as compared to the stress experienced when the top surfaces of the support contacts are co-planar relative to a horizontal datum plane. In another embodiment, a difference in height between the top surface of support contact 112 and top surface of support contact 116 is approximately 0.3 mm. This height difference is meant to be exemplary and not meant to be limiting, as any suitable height difference may be utilized.

FIG. 5B illustrates end effector 100 having support contacts 106 and 110 disposed thereon. End effector 100 has support contacts 106 and 110 having top surfaces which are not coplanar as discussed above. In one embodiment, the distance between a top surface of support contact 110 and a top surface of support contact 106 is approximately 0.3 mm. As mentioned above, this is meant to be exemplary and not limiting. It should be noted that any number of height differences may be employed for the support contacts. One effect of the height difference is to intentionally induce a shape change of the wafer surface. For example, with reference to FIGS. 1A-C, the container support contacts may be arranged with support contact 112 lower than support contacts 116 and 114. End effector 100 may have a similar configuration with support contact 106 lower than support contacts 108 and 110. Of course, any number of combinations of heights may be utilized in the embodiments described herein.

One skilled in the art will appreciate that the materials for the end effector and container are compatible with the semiconductor substrates and the corresponding semiconductor processing environments. It should be noted that the actual contact points may be selected for properties that have engineered characteristics for particular wafer applications. Such properties can include elevated temperature resistance, electrostatic discharge or conductivity properties, chemical inertness, high or low friction, etc. In addition, the heights of the top surfaces of the support contacts may be offset through variation of the end effector arm on which the support contact is affixed to. For example, the end effector arm may have a different thickness in different areas, i.e., the thickness of the back support relative to the extending arms of the outer ring. Alternatively, the end effector may be angled in pitch relative to a horizontal datum plane to obtain optimum positioning of the wafer relative to the container structure and/or process chucks. In addition, the end effector can vary the planar orientation of the extending arms of the outer ring. Of course, the same may be done to the support arms of the container to vary the planar height of the top surface of the support contacts.

FIG. 6 is a simplified schematic diagram of a container in accordance with one embodiment of the invention. The base member 204 shown extends upward from the container door 12. The base member 204 may comprise a structure separate from the container door 12 or may comprise a structure that is part of the container door 12. Any number of support arms 104 may extend or project from a base member 204, and the number of support arms 104 simply determines how many wafers may be stored in a carrier if the support structure is located within a carrier (each pair of support arms 104, or storage shelf, supports a single wafer). Alternatively, the support arms may be a monolithic unit. In another embodiment, two or more support arms may support a single wafer. In this embodiment, each wafer W is supported by a pair of support arms 104, which may be referred to as a storage shelf. Each pair of support arms 104 preferably support the wafer W in a substantially horizontal orientation so that the wafers W are substantially parallel to each other, with deflection and other stresses minimized. As mentioned above, in one embodiment this is achieved by offsetting the relative heights of the support contacts on the support arms.

Support arms 104 may be molded or independent pieces secured to the base member 204. FIG. 6 is meant to be exemplary and not limiting as other support arm architecture as described above may be incorporated into the container. In one embodiment, the container may have a side opening as illustrated in FIGS. 2A and 2B. Of course, the container may also be bottom or top opening. In another embodiment, the container may be an open structure enabling flexible access to the wafers.

FIGS. 7A through 7C are simplified schematic diagrams illustrating a top view of a container and end effector for supporting a substrate in accordance with one embodiment of the invention. End effector 100 is configured to support substrate 122 and transfer the substrate to or from container 102. End effector 100 includes support arm extension 101, first arm 103 and second arm 105 extending from the support arm extension. First arm 103 includes a pad support arm extension which includes pad supports 109a. Second arm extension 105 includes a corresponding pad support arm extension with support features 109b affixed thereto. It should be appreciated that the support for substrate 122 provided by end effector 100 is an alternative embodiment to the embodiment described in FIGS. 1A through 1C. In the embodiment described with regards to FIGS. 7A through 7C, the pad support arm extensions of end effector 100 are spread apart so as not to exceed a diameter of substrate 122. Thus, the outer profile of end effector 100 is not larger than the diameter of substrate 122 in this embodiment.

Container 102 for this embodiment includes arms 99a and 99b which have corresponding support contacts 107a and 107b disposed thereon. The configuration of arms 99a and 99b enable the support arm extensions from end effector 100 to travel under the bottom region of wafer 122 in an area inside the diameter of the wafer toward a backside of container 102. While four corresponding contact points are illustrated for the configuration of FIGS. 7A through 7C, it will be apparent to one skilled in the art that other support configurations may be provided with minor adjustments to the end effector or container support arms. For example, end effector 100 may have an additional support contact similar to the support contact 106 of FIGS. 1A through 1C. As described above, the height of the various support contacts may be offset in order to provide additional support for a 450 millimeter (mm) substrate and the deflections encountered with such a substrate. It should be appreciated that the shape of the top surfaces of the contact pads may be all similar, all different, or some combination of the two.

The material utilized for the contact pads is any suitable material compatible with the semiconductor wafer and process operations. The materials include polymers with high or low coefficients of friction, as well as materials with other desired or engineered characteristics, such as conductivity, etc. The contact pads may also have features that enable airflow or fluid movement that enable vacuum or air pressure to be applied for holding wafers, releasing wafers, or sensing wafers. Such means may be applied to the contact pads singly or as a group. In one embodiment, the 450 mm substrate behaves as a flexible membrane during transport and support operations. As depicted in FIGS. 7B and 7C, end effector 100 can move into and out of container 102 in a planar (X) direction and then be adjusted in a vertical (Z) direction to pick and place various substrates 122.

While end effector 100 is illustrated as an integral piece with the pad support arm extension and the first and second arms as a unitary block, end effector 100 may be composed of various pieces affixed to each other in another embodiment. That is, first arm 103 and second arm 105 may be pivotably mounted to support arm extension 101. One skilled in the art will appreciate that other mounting configurations for the end effector besides a unitary block are possible. In addition, container 102 may have a plurality of cantilevered arms 99a and 99b to support a number of substrates 122. In one embodiment, a pitch between the cantilevered arms is approximately 10 millimeters with a range of approximately 8 millimeters to 12 millimeters. However, this design is just one embodiment and numerous other configurations with a pitch of less than or greater than 10 millimeters is possible.

Still referring to FIGS. 7A-7C, the elimination of the third arm depicted in FIGS. 1A-C, allows for a larger clearance area or clearance budget as the substrate may sag at the peripheral region where the third arm is depicted in FIGS. 1A-C. In addition, the embodiments of FIGS. 7A-C illustrate that support contacts for the container 102 correlate to the support contacts for the end effector 100. That is, support contacts 107a and 109a are correlated and support contacts 107b and 109b are correlated. In one embodiment a distance between the correlated support contacts is about 10 millimeters, however, this is not meant to be limiting. This correlation ensures that the support profile for the substrate is maintained on either the end effector or the container supports. Thus, when the two support arms of the container provide a support profile where the shape of the wafer slightly sags between the support arms and on the peripheral edges outside of the support arms, this support profile is maintained on the end effector when the support points are correlated.

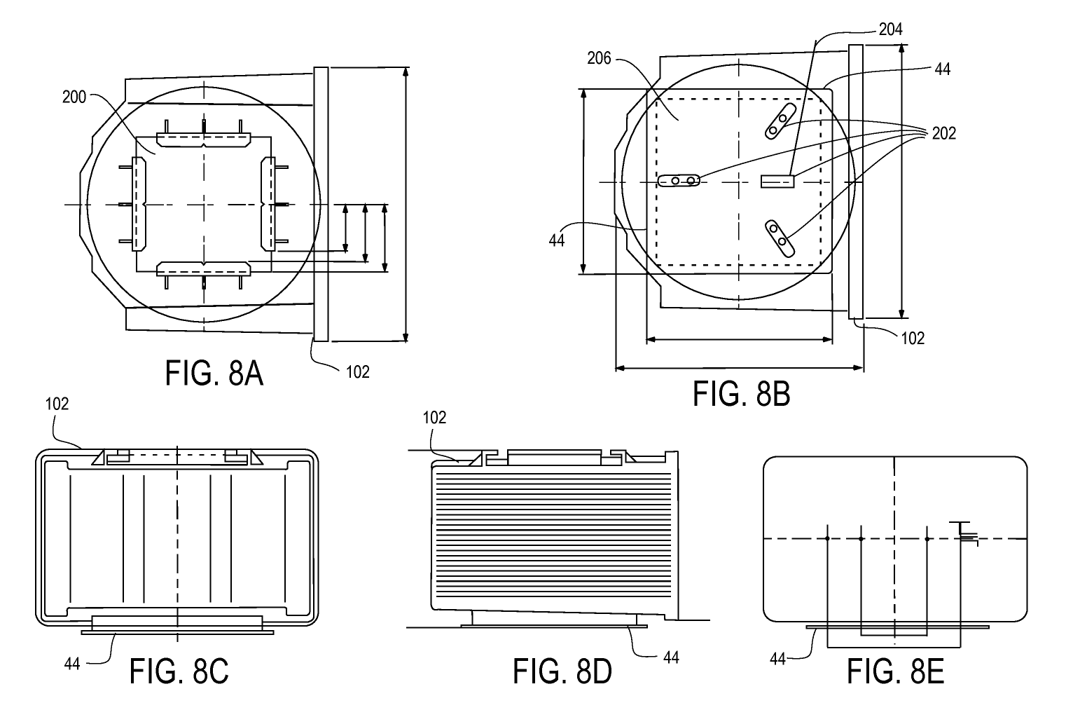

FIGS. 8A through 8E illustrate a container configured to support substrates in accordance with one embodiment of the invention. Container 102 includes planar recess zone 200 configured to enable a top grip clearance so that container 102 may be supported from the top and moved accordingly by this top flange. In FIG. 8B, a conveyor/kinematic pin plate 206 is disposed on a bottom surface of container 102. The bottom view of container 102 in FIG. 8B is illustrated where kinematic pin locations 202 are provided for support and alignment purposes for container 102. In addition, hold down feature 204 is provided. FIGS. 8C, 8D, and 8E illustrate back, side, and front views, respectively, of container 102 that can contain different amounts of wafers. In FIGS. 8B-E container 102 includes bottom plate 44, which is a square plate for utilization with a conveyor transport of a fabrication facility. Plate 44 is less than the width of the container as illustrated in FIG. 8B. An outer edge of plate 44 extends continuously around the edge and can function as a continuous conveyor strip or resting guide for a conveyor. The square configuration of plate 44 enables the container to be oriented in any manner where a side of the plate is parallel to the direction of the motion of the conveyor without having to reconfigure the conveyor. Thus, four different orientations of the container on the conveyor are possible in this embodiment.

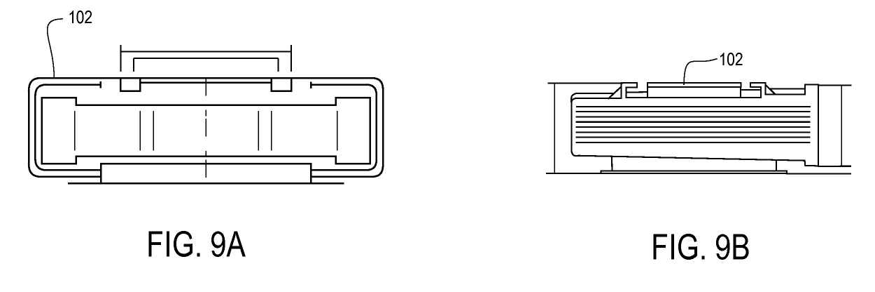

FIGS. 9A and 9B illustrate a smaller capacity front opening unified pod (FOUP) in accordance with one embodiment of the invention. In FIGS. 9A and 9B, similar features as the container of FIGS. 8A through 8D are included, with the exception that a smaller amount of wafers will be supported within container 102. It should be appreciated that container 102 may be configured to support any number of wafers, including one or more. In addition, where a container supports a single wafer, a cantilevered structure for the support arms is not necessary. That is, ridges or some other features disposed on the bottom of the container that may be molded or affixed thereto, provide support for wafers without the need for cantilevered support arms.

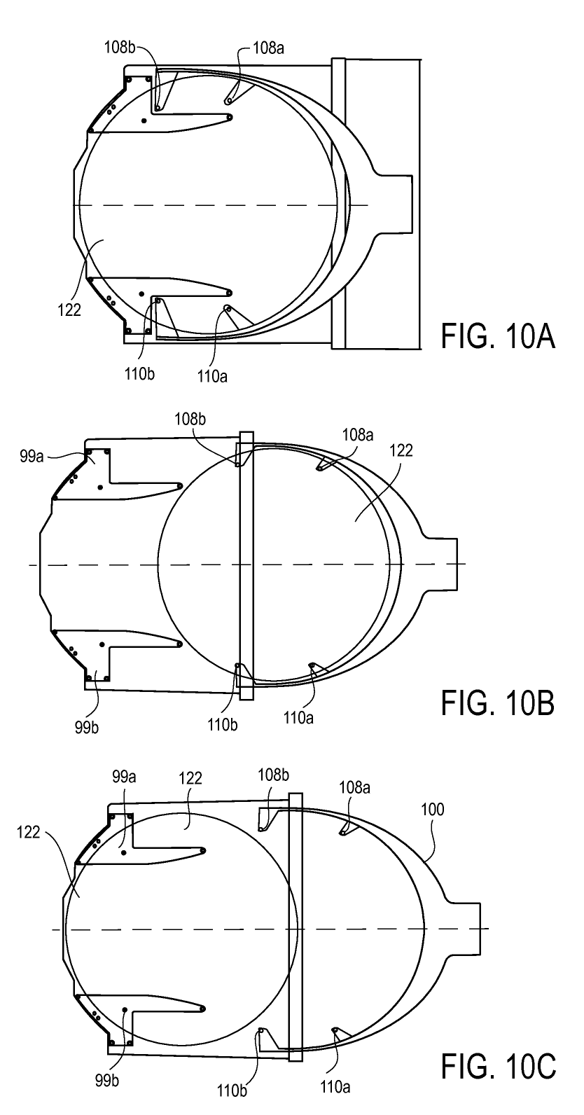

FIGS. 10A through 10C illustrate an alternative end effector design in accordance with one embodiment of the invention. End effector 100 has a profile that proceeds along an outer peripheral edge of substrate 122 with support arms having substrate contacts 108a, 108b, 110a, and 110b disposed thereon. In this embodiment, end effector 100 will have a profile that is larger than the diameter of wafer 122, as opposed to the embodiment described with regard to FIGS. 7A through 7C where the end effector does not have a profile larger than the wafer diameter. Support contacts 108a, 108b, 110a, and 110b of end effector 100 provide support for wafer 122, while cantilevered arms 99a and 99b and corresponding support contacts disposed thereon will support wafer 122 when disposed within container 102. The movement of end effector 100 is illustrated in FIGS. 10B and 10C and enables X and Z movement in order to transport wafers to and from container 102. As illustrated in FIGS. 10A through 10C, support contacts or pads 108a, 108b, 110a, and 110b and corresponding support arm extensions on which the support features are disposed, are configured so that corresponding support points are similarly situated in order to support substrate 122 similarly, irrespective of whether the substrate is supported in the container or on the end effector. Consequently, substrate 122 experiences a minimal amount of difference in deflection or support stresses when being supported on the end effector or in the container, as mentioned above. As illustrated, there is a close correlation in this embodiment, as well as in FIGS. 7A-C, between corresponding locations of the support points of the end effector 100 and support points container 102.

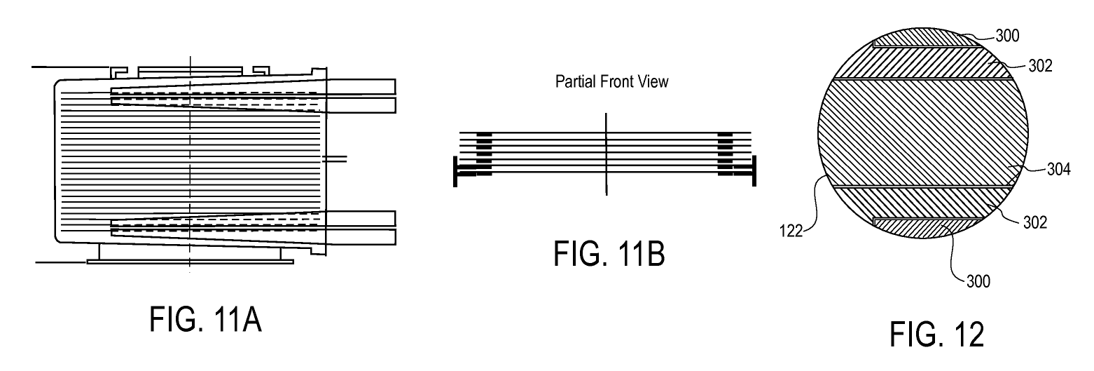

FIGS. 11A and 11B illustrate a side and front view, respectively, of container 102 in accordance with one embodiment of the invention. As mentioned previously, in one embodiment, container 102 is configured to support substrates 122 with a 10 millimeter wafer pitch.

FIG. 12 is a simplified schematic diagram illustrating areas of support for substrate or semiconductor wafer 122. In region 300 the end effector supports substrate 122. In region 302, the support arms for the container support substrate 122. It should be appreciated that FIG. 12 is exemplary and not meant to be limiting as alternative support zones may be configured based on the deflection and characteristics of substrate 122. That is, as substrates transition from a 300 millimeter to 450 millimeter diameter, the deflection experienced by the substrates during transport and storage may be characterized and the container and end effector support may be tailored to minimize any deflection. For example, the support zones for the end effector may include a central area 304 of substrate 122, i.e., where an internal end effector is utilized. In addition to the areas of support, the contact pads may be manipulated, e.g., by varying the plane of support as discussed above, to minimize deflection.

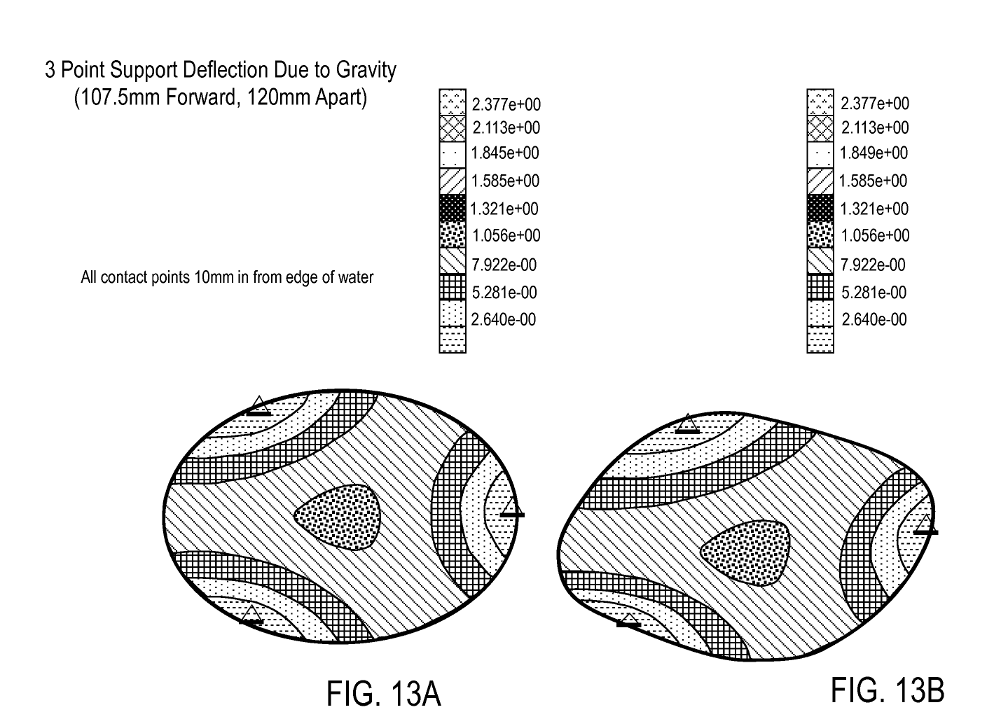

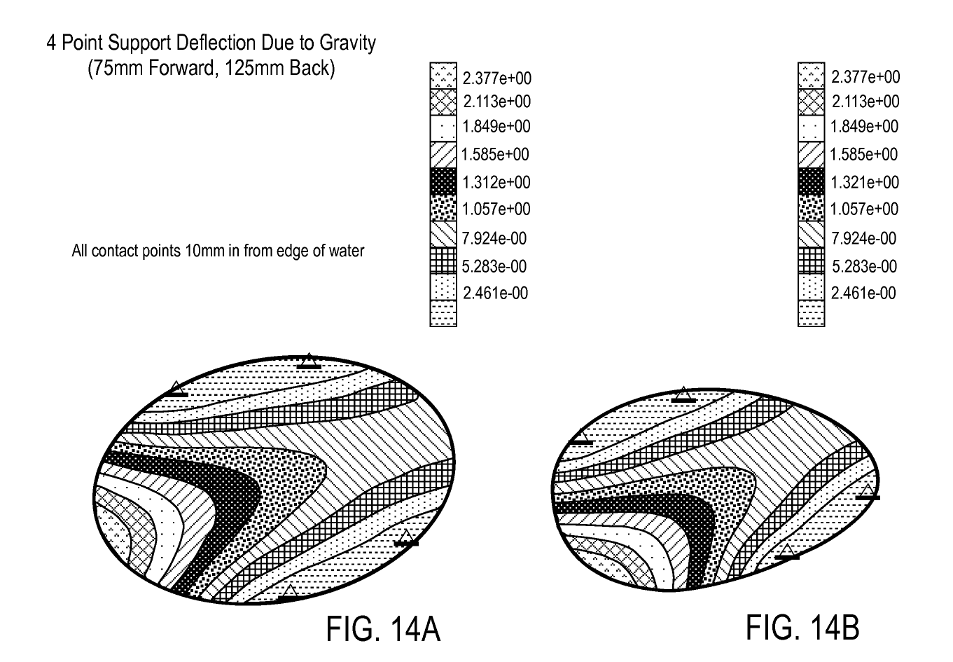

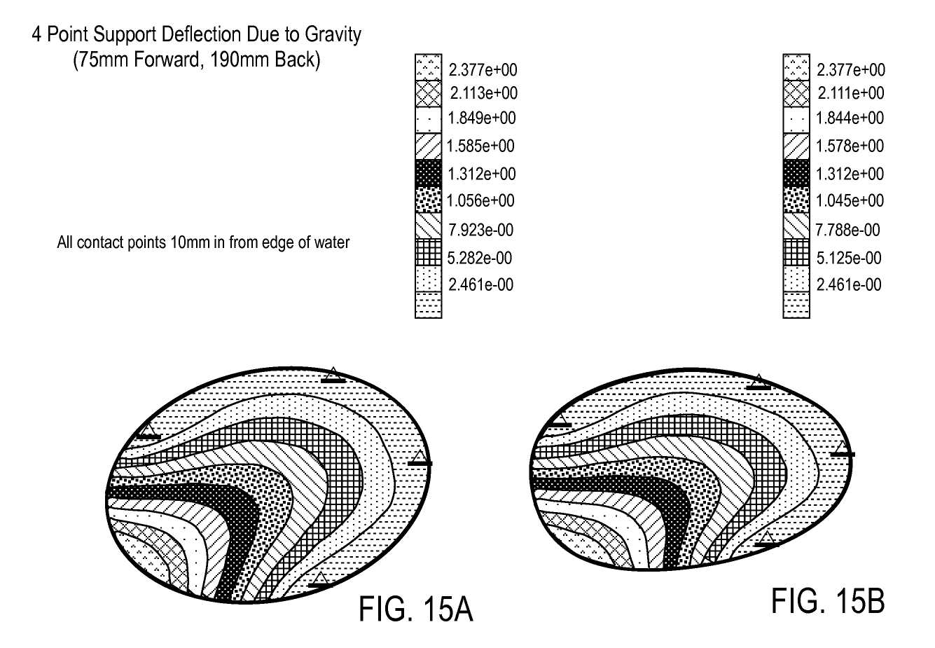

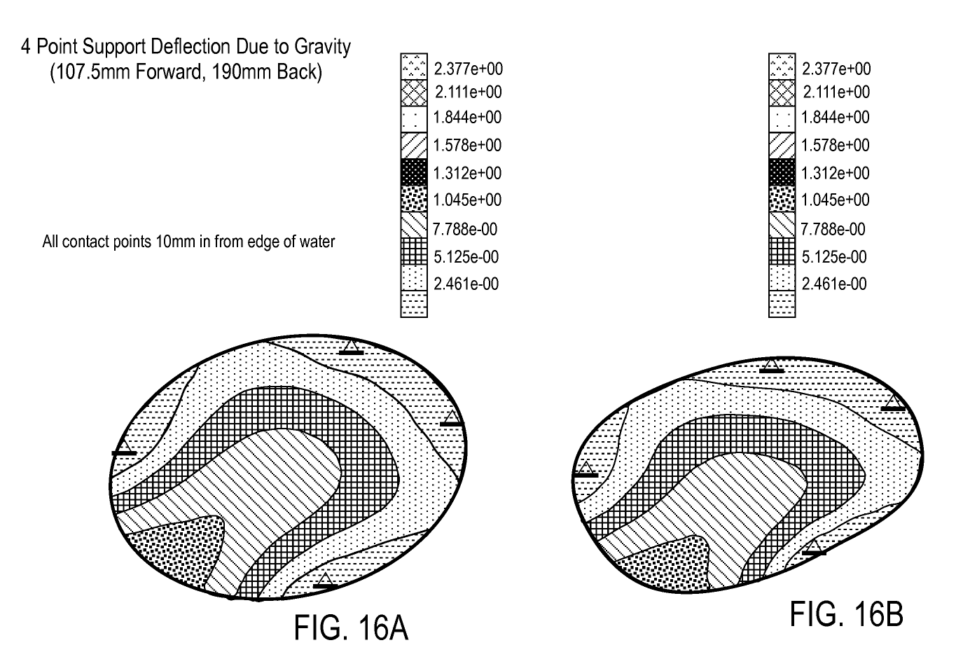

FIGS. 13A through 16B illustrate various modeling diagrams depicting support deflection due to gravity and its impact on the wafer. As mentioned above, as the relative thickness of the wafers decreases, while the diameter is increasing in the transition from 300 to 450 mm wafers, the 450 mm wafer begins to act more like a flexible membrane. Thus, through mathematical modeling, the deflection experienced according to various support techniques to minimize deflection can be evaluated and the optimum support technique can be designed for the end effector and containers described herein based on this modeling. In FIGS. 13A and 13B, the deflection for support with three points with the points 120 degrees apart is shown. In FIGS. 14A and 14B, the deflection for support with four points is shown. FIGS. 15A-16B illustrate additional four point deflection modeling with the forward and back support points moved to various locations. In each of FIGS. 13A-16B, the “A” figures are flat views of the graph at an angle, and the “B” view is a 3D representation of the same graph showing an exaggerated bending of the wafer or substrate. The distance listed as forward and back for each figure represents how far forward the support contacts are from the center of gravity and how far backward the support contacts are from the center of gravity. One skilled in the art will appreciate that the support pattern for the substrate container and the end effector will be substantially the same when the support points are correlated but the peak deflection points will be at opposing ends in some embodiments as the end effector and the substrate container come in from opposing edges of the substrate.

In one alternative exemplary embodiment, the support arms or tines for the container illustrated in FIGS. 1A-C, 7A-C, and 10A-C may extend from side surfaces into an interior portion of the container. That is, where the end effector does not need to access the peripheral edge of the substrate, e.g., an internal end effector, multiple support arms or surface features can extend from the side and/or back surfaces of the container to provide support points for the substrate. In one embodiment, the multiple support arms may be configured to support the substrate at a support point 25 mm from a peripheral edge of the substrate. Of course, multiple designs may be utilized for extending support arms from the sides of the container toward an internal region of the container.

In yet another alternative embodiment, the end effector may be two or more independent arms rather than the coupled arms illustrated in the above embodiment. The two or more independent arms may proceed in an X direction to enter or exit the container and then transfer the substrate directly to a process tool. The two independent arms may be coupled to a horizontal rod that provides the lateral translation (X direction) and the horizontal rod can be capable of being moved in a vertical (Z) direction. As mentioned above, the contact supports may be located to be proximate to the container contact supports. One skilled in the art will appreciate that the substrate obtained from the container in this embodiment may be directly delivered into a process tool as there is no need to turn or rotate the end effector. In another embodiment, the independent support arms may be cantilevered to substantially mimic the design of the container so that multiple substrates may be picked or placed from the container.

It should be appreciated that many of the inventive concepts described above would be equally applicable to the use of non-semiconductor manufacturing applications as well as semiconductor related manufacturing applications. Exemplary uses of the inventive concepts may be integrated into solar cell manufacturing and related manufacturing technologies, such as; single crystal silicon, polycrystalline silicon, thin film, and organic processes, etc. In addition, the embodiments may be extended to substrates having a shape other than a circular shape, e.g., square, rectangular, and other geometric shapes may take advantage of the embodiments described herein.

Any of the operations described herein that form part of the invention are useful machine operations. The invention also relates to a device or an apparatus for performing these operations. The apparatus can be specially constructed for the required purpose, or the apparatus can be a general-purpose computer selectively activated, implemented, or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

1. A system for transporting a substrate, comprising:
a container configured to store the substrate, the container including a set of support arms that extend within the container, the support arms of the container affixed with a first plurality of support points, the support arms of the container extending along a first dimension, the support points of the first plurality are configured to support a substrate, the first plurality includes a first subset and a second subset, the support points of the first subset located on a first side of a diameter of the substrate, the diameter extending along a second dimension that is perpendicular to the first dimension, the support points of the second subset located on a second side of the diameter, the first side located opposite to the second side; and
an end effector configured to extend within the container to support the substrate, the end effector including a support body, the end effector including a set of support arms extending from the support body, the support arms of the end effector extending along the first dimension, the support arms of the end effector configured to support the substrate, the support arms of the end effector affixed with a second plurality of support points, the second plurality includes a third subset and a fourth subset, the support points of the third subset located on the first side of the diameter, and the support points of the fourth subset located on the second side of the diameter.

2. The system of claim 1, wherein the support arms of the end effector are spread apart to exceed the diameter.

3. The system of claim 1, wherein the support arms of the end effector are spread apart to avoid exceeding the diameter.

4. The system of claim 1, wherein the container includes an enclosure, a first inner side and a second inner side, a first one of the support arms of the container includes an outer edge that faces the first inner side, a second one of the support arms of the first set includes an outer edge that faces the second inner side, a first distance formed between the first inner side and the outer edge of the first support arm, a second distance formed between the second inner side and the outer edge of the second support arm.

5. The system of claim 4, wherein the first and second distances allow vertical movement, within the enclosure, of the support arms of the end effector without contacting the substrate and the support arms of the container.

6. The system of claim 4, wherein when the substrate rests on the support points of the first plurality, a portion of a peripheral edge of the substrate extends beyond the outer edges of the support arms of the container.

7. The system of claim 1, wherein a number of support points of the first plurality is equal to a number of support points of the second plurality.

8. The system of claim 1, wherein the support points of the first plurality are apart from each other by the same angle.

9. The system of claim 1, wherein the end effector is configured to access a peripheral edge of the substrate.

10. The system of claim 1, wherein the end effector is configured to access a central area of the substrate.

11. The system of claim 1, wherein the support points of the first plurality are configured to support an external edge of the substrate and the support points of the second plurality are configured to support the external edge.

12. The system of claim 1, wherein the support points of the first plurality are configured to support a lower surface of the substrate and the support points of the second plurality are configured to support the lower surface.

13. A container for storing a substrate, comprising a set of support arms that extend within the container, the support arms affixed with a plurality of support points, the support points are configured to support the substrate, the support arms of the container extending along a first dimension, the plurality of support points includes a first subset and a second subset, the support points of the first subset located on a first side of a diameter of the substrate, the diameter extending along a second dimension that is perpendicular to the first dimension, the second subset located on a second side of the diameter, the first side located opposite to the first side.

14. The container of claim 13, further comprising an enclosure, a first inner side and a second inner side, a first one of the support arms includes an outer edge that faces the first inner side, a second one of the support arms includes an outer edge that faces the second inner side, a first distance formed between the first inner side and the outer edge of the first support arm, a second distance formed between the second inner side and the outer edge of the second support arm.

15. The container of claim 14, wherein the first and second distances allow vertical movement, within the enclosure, of support arms of an end effector without contacting the substrate and the support arms of the container.

16. The container of claim 14, wherein when the substrate rests on the support points, a portion of a peripheral edge of the substrate extends beyond the outer edges of the support arms.

17. The container of claim 13, wherein the support points are apart from each other by the same angle.

18. The container of claim 13, wherein the support points are configured to support an external edge of the substrate.

19. The container of claim 13, wherein the support points are configured to support a lower surface of the substrate.

20. A system for transporting a substrate, comprising;
a substrate container having a support structure disposed within a housing assembly, the support structure having a plurality of support extensions extending into an inner region of the housing assembly, the plurality of support extensions arranged as horizontally coplanar pairs, wherein support extensions of different horizontal planes are vertically aligned;
an end effector adapted to support a peripheral region of the substrate outside of the horizontally coplanar pairs of a surface of a substrate housed within the substrate container, the end effector having,
a first arm extending from an end effector support body, and
a second arm extending from the end effector support body, the first and the second arms supporting the substrate at support points proximate to support points of the support extensions of the substrate container,
wherein the first and the second arms each include multiple support features, a height of one of the support features on the first arm being different than a height of another of the support features on the second arm.
